(19) United States
(12) Patent Application Publication
(10) Pub. No.: US 2012/0218242 A1
(43) Pub. Date: Aug. 30, 2012

(54) PIXEL STRUCTURE, DRIVING METHOD AND DRIVING SYSTEM OF HYBRID DISPLAY APPARATUS

(75) Inventors: Chang-An Ho, Keelung City (TW); Chen-Wei Lin, Kaohsiung City (TW); Chih-Chieh Hsu, Hsinchu City (TW)

(73) Assignee: INDUSTRIAL TECHNOLOGY RESEARCH INSTITUTE, Hsinchu (TW)

(21) Appl. No.: 13/108,006

(22) Filed: May 16, 2011

(30) Foreign Application Priority Data
Feb. 24, 2011 (TW) 100106237

(51) Int. Cl. G09G 5/00; H01L 33/08

(52) U.S. Cl. 345/211; 257/88; 257/E33.012

(57) ABSTRACT

A pixel structure, a driving method and a driving system of a hybrid display apparatus are provided. The pixel structure includes a scan line, a data line, a first active device, a first signal line, a second signal line, an electro-phoretic display device, a second active device and an organic light emitting diode device. The first active device is electrically connected to the scan line and the data line. The electro-phoretic display device is electrically connected to the first active device and the first signal line. The second active device is electrically connected to the first active device and the first signal line. The organic light emitting diode device is electrically connected to the second active device and the second signal line.

### CROSS-REFERENCE TO RELATED APPLICATION

This application claims the priority benefit of Taiwan application serial no. 100106237, filed Feb. 24, 2011. The entirety of the above-mentioned patent application is hereby incorporated by reference herein and made a part of this specification.

### TECHNICAL FIELD

The disclosure relates to a pixel structure, a driving method and a driving system of a hybrid display apparatus.

### BACKGROUND

In recent years with the advancements of various types of display technologies, after continual development, display devices such as electro-phoretic displays, liquid crystal displays, plasma displays, and organic light emitting diode displays have been gradually commercialized and applied in display devices having various sizes and areas. With the increasing use of portable electronic devices, products such as electronic papers (e-papers) and electronic books (e-books) have gradually caught the attention of the market.

In particular, the electro-phoretic displays have advantages of light and thin, low power consumption, and wide view angle. Users can easily read or use the electro-phoretic displays under any light sources. In addition, the organic light emitting diode displays also have advantages of light and thin, flexible, high chrominance and high response rate.

### SUMMARY

A pixel structure of a hybrid display apparatus includes a scan line, a data line, a first active device, a first signal line, a second signal line, an electro-phoretic display device, a second active device and an organic light emitting diode device. The first active device is electrically connected to the scan line and the data line. The electro-phoretic display device is electrically connected to the first active device and the first signal line. The second active device is electrically connected to the first active device and the first signal line. The organic light emitting diode device is electrically connected to the second active device and the second signal line.

A method of driving a hybrid display apparatus comprises providing a hybrid display apparatus comprising a plurality of pixel structures, and each of the pixel structures is as above mentioned. When the hybrid display apparatus is displayed with an electro-phoretic displaying mode, a driving voltage is applied to the scan lines of the pixel structures, a first driving voltage is applied to the data lines of the pixel structures, and a second driving voltage is applied to the first signal lines and the second signal lines of the pixel structures. When the hybrid display apparatus is displayed with an organic light emitting diode displaying mode, the driving voltage is applied to the scan lines of the pixel structures, a third driving voltage is applied to the data lines and the first signal lines of the pixel structures, and a ground voltage or zero voltage is applied to the second signal lines of the pixel structures. When the hybrid display apparatus is displayed with a hybrid displaying mode, the driving voltage is applied to the scan lines of the pixel structures, a fourth driving voltage is applied to the data lines of the pixel structures, a fifth driving voltage is applied to the first signal lines of a portion of the pixel structures, and a sixth driving voltage is applied to the first signal lines of another portion of the pixel structures.

A driving system of a hybrid display apparatus comprises a hybrid display apparatus, a detection unit and a control unit. The hybrid display apparatus comprises a plurality of pixel structures, and each of the pixel structures is as above mentioned. The detection unit is electrically connected to the hybrid display apparatus. The control unit is electrically connected to the hybrid display apparatus and the detection unit. When the hybrid display apparatus is powered-on, the detection unit performs a detecting step, such that the electro-phoretic display devices of the pixel structures are performed with a resetting process. When an image signal is transmitted to the control unit, the detection unit detects the image signal and transmits a detecting signal to the control unit, and the control unit drives the hybrid display apparatus to display an image in accordance with the detecting signal.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram illustrating a pixel array of a hybrid display apparatus according to an exemplary embodiment.

FIG. 2 is a schematic diagram illustrating one pixel structure of the pixel array in FIG. 1.

FIG. 3A is a schematic top view showing a pixel structure according to an exemplary embodiment.

FIG. 3B is a schematic cross-sectional view along the line I-I′ of the pixel structure in FIG. 3A.

FIG. 4 is a schematic diagram illustrating a pixel structure of a hybrid display apparatus according to another exemplary embodiment.

FIG. 5 is a schematic diagram illustrating a method of driving a hybrid display apparatus with an electro-phoretic displaying mode according to an exemplary embodiment.

FIG. 6 and FIG. 7 are schematic equivalent circuit diagrams of the pixel structure in FIG. 5.

FIG. 8 is a schematic diagram illustrating a method of driving a hybrid display apparatus with an organic light emitting diode displaying mode according to an exemplary embodiment.

FIG. 9 is a schematic equivalent circuit diagram of the pixel structure in FIG. 8.

FIG. 10 is a schematic diagram illustrating a method of driving a pixel array of a hybrid display apparatus with a hybrid displaying mode according to an exemplary embodiment.

FIG. 11 is a schematic time sequence diagram illustrating a method of driving a pixel array of a hybrid display apparatus with a hybrid displaying mode according to an exemplary embodiment.

FIG. 12 is a schematic diagram illustrating a driving system of a hybrid display apparatus according to an exemplary embodiment.

FIG. 13 is a schematic time sequence diagram illustrating a driving method of a hybrid display apparatus according to an exemplary embodiment.

### DETAILED DESCRIPTION OF DISCLOSED EMBODIMENTS

In the disclosure, the electro-phoretic display devices and the organic light emitting diode devices are integrated to a display apparatus to form a hybrid display apparatus. This hybrid display apparatus can be displayed with a suitable displaying mode in accordance with demands. In particular, if the hybrid display apparatus is displayed with a hybrid displaying mode, reading convenience can be enhanced. Therefore, this hybrid display apparatus is beneficial to apply to the electronic papers (e-papers) and the electronic books (e-books).

### Pixel Structure

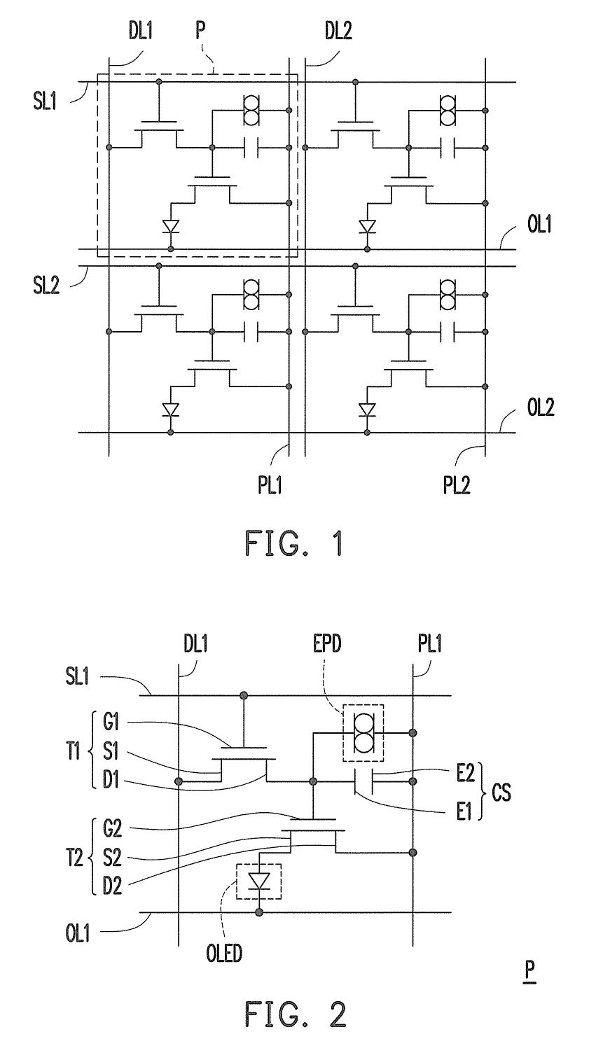

FIG. 1 is a schematic diagram illustrating a pixel array of a hybrid display apparatus according to an exemplary embodiment. As shown in FIG. 1, the hybrid display apparatus comprises a pixel array constituted of a plurality of pixel structures P. The pixel array includes a plurality of scan lines SL1˜SLi (the figure only shows SL1 and SL2 for illustration), a plurality of data lines DL1˜DLj (the figure only shows DL1 and DL2 for illustration), a plurality of first active devices T1, a plurality of second active devices T2, a plurality of first signal lines PL1˜PLj (the figure only shows PL1 and PL2 for illustration), a plurality of second signal lines OL1˜OLi (the figure only shows OL1 and OL2 for illustration), a plurality of electro-phoretic display devices EPD and a plurality of organic light emitting diode devices OLED.

The following description for the pixel structure P is one pixel structure of the pixel array in FIG. 1. Generally, pixel structures P of a pixel array are substantially the same or similar, and therefore one skilled in the art can understand the pixel array based on the following description for the one pixel structure P.

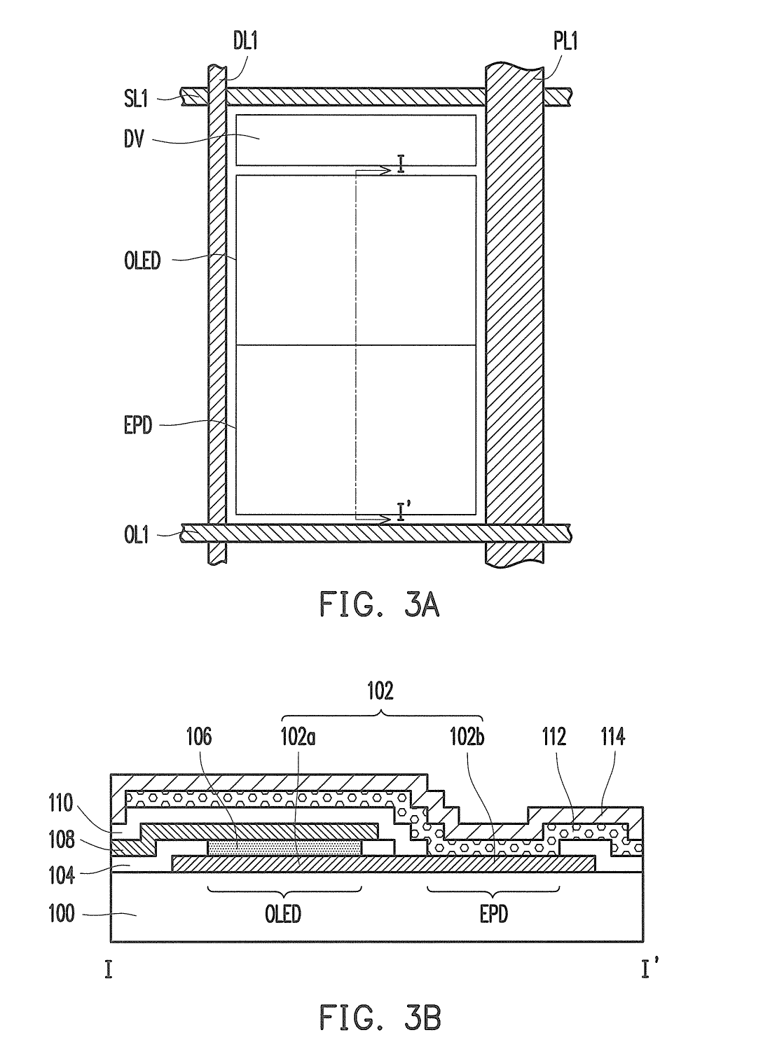

FIG. 2 is a schematic diagram illustrating one pixel structure of the pixel array in FIG. 1. FIG. 3A is a schematic top view showing a pixel structure according to an exemplary embodiment. FIG. 3B is a schematic cross-sectional view along the line I-I′ of the pixel structure in FIG. 3A. Referring to, FIG. 2, FIG. 3A and FIG. 3B, the pixel structure P comprises a scan line SL1, a data line DL1, a first active devices T1, a second active devices T2, a first signal lines PL1, a second signal lines OL1, an electro-phoretic display device EPD and an organic light emitting diode device OLED on a substrate 100.

The substrate 100 is a transparent substrate, and it can be a rigid substrate or a flexible substrate. The substrate 100 is mainly used to carry devices or films. According to the exemplary embodiment, the scan line SL1 and the data line DL1 are not parallel to each other, and an insulating layer (not shown) is disposed between the scan line SL1 and the data line DL1 so as to electrically isolate the scan line SL1 and the data line DL1. The first signal line PL1 is disposed parallel to the data line DL1, the first signal line PL1 is not parallel to the scan line SL1, and an insulating layer (not shown) is disposed between the first signal line PL1 and the scan line SL1 so as to electrically isolate the first signal line PL1 and the scan line SL1. The second signal line OL1 is disposed parallel to the scan line SL1, the second signal line OL1 is not parallel to the data line DL1, and an insulating layer (not shown) is disposed between the second signal line OL1 and the data line DL1 so as to electrically isolate the second signal line OL1 and the data line DL1.

The first active device T1 is electrically connected to the scan line SL1 and the data line DL1. According to the exemplary embodiment, the first active device T1 comprises a first gate G1, a first source S1 and a first drain D1, the first gate G1 is electrically connected to the scan line SL1, and the first source S1 is electrically connected to the data line DL1. The second active device T2 is electrically connected to the first active device T1 and the first signal line PL1. According to the exemplary embodiment, the second active device T2 comprises a second gate G2, a second source S2 and a second drain D2, the second gate G2 is electrically connected to the first drain D1 of the first active device T1, and the second source S2 is electrically connected to the first signal line PL1. The first active device T1 and the second active device T2 may be top-gate thin film transistors or bottom-gate thin film transistors. The first active device T1 and the second active device T2 are also referred to a driving device DV of a pixel structure, as shown in FIG. 3A, and the driving device D is usually disposed in an edge region of the pixel structure.

The organic light emitting diode device OLED is electrically connected to the second active device T2 and the second signal line OL1. In the exemplary embodiment, the organic light emitting diode device OLED is electrically connected to the second drain D2 of the second active device T2. The organic light emitting diode device OLED comprises a first electrode layer 102a, an organic light emitting layer 106 and a second electrode layer 108. The first electrode layer 102a is referred to an anode and is electrically connected to the second drain D2 of the second active device T2. An insulating layer 104 is disposed on the first electrode layer 102a and exposes a portion of the first electrode layer 102a. The organic light emitting layer 106 is disposed on the exposed first electrode layer 102a and comprises a red organic light emitting material, a green organic light emitting material or a blue organic light emitting material. The second electrode layer 108 is referred to a cathode and is electrically connected to the second signal line OL1.

The electro-phoretic display device EPD is electrically connected to the first active device T1 and the first signal line PL1. In the exemplary embodiment, the electro-phoretic display device EPD is electrically connected to the first drain D1 of the first active device T1. The electro-phoretic display device EPD comprises a first electrode layer 102b, a second electrode layer 114 and an electro-phoretic display medium 112. The first electrode layer 102b is referred to an anode and is electrically connected to the first drain D1 of the first active device T1. The second electrode layer 114 is referred to a cathode and is electrically connected to the first signal line PL1. The electro-phoretic display medium 112 is disposed between the first electrode layer 102b and the second electrode layer 114.

According to the exemplary embodiment, the electro-phoretic display medium 112 and the second electrode layer 114 of the electro-phoretic display device EPD cover the organic light emitting diode device OLED, as shown in FIG. 3B. An insulating layer 110 is further disposed between the second electrode layer 108 of the organic light emitting diode device OLED and the electro-phoretic display medium 112 of the electro-phoretic display device EPD to isolate the second electrode layer 108 and the electro-phoretic display medium 112.

In the exemplary embodiment, the first electrode layer 102a of the organic light emitting diode device OLED and the first electrode layer 102b of the electro-phoretic display device EPD are the same film layer 102, and the film layer 102 is made of a transparent conductive material, such as indium tin oxide (ITO), indium zinc oxide (IZO), aluminum tin oxide (ATO), aluminum zinc oxide (AZO), indium germanium zinc oxide or other suitable metal oxide materials.

Since the first electrode layer 102a of the organic light emitting diode device OLED is made of a transparent conductive material and the substrate 100 is also a transparent substrate, the color light generated from the organic light emitting layer 106 of the organic light emitting diode device OLED can emit out through the substrate 100.

In addition, the first electrode layer 102b of the electro-phoretic display device EPD is made of a transparent conductive material, and the second electrode layer 114 of the electro-phoretic display device EPD is made of a high reflective metal material. If the external light emits toward the substrate 100 and the passes through the first electrode layer 102b and the electro-phoretic display medium 112, the light may be reflected by the second electrode layer 114. At this time, the electro-phoretic display device EPD is at a white state. If the external light emits to the substrate 100 and passes through the first electrode layer 102b and then is absorbed by the electro-phoretic display medium 112, the electro-phoretic display device EPD is at a black state.

In the exemplary embodiment, the pixel structure P may further comprises a storage capacitor CS, as shown in FIG. 2. The storage capacitor CS comprises a first capacitor electrode E1 and a second capacitor electrode E2. The first capacitor electrode E1 is electrically connected to the first drain D1 of the first active device T1, and first capacitor electrode E1 is also electrically connected to the second gate G2 of the second active device T2. The second capacitor electrode E2 is electrically connected to the second source S2 of the second active device T2, and the second capacitor electrode E2 is also electrically connected to the first signal line PL1.

The pixel structure P of the exemplary embodiment comprises the electro-phoretic display device EPD and the organic light emitting diode device OLED, and the electro-phoretic display device EPD and the organic light emitting diode device OLED are driven by the first active device T1 and the second active device T2. Therefore, the hybrid display apparatus having said pixel structures P can display an image with an electro-phoretic displaying mode, an organic light emitting diode displaying mode or a hybrid displaying mode. The driving method of the hybrid display apparatus is described in the subsequent paragraphs.

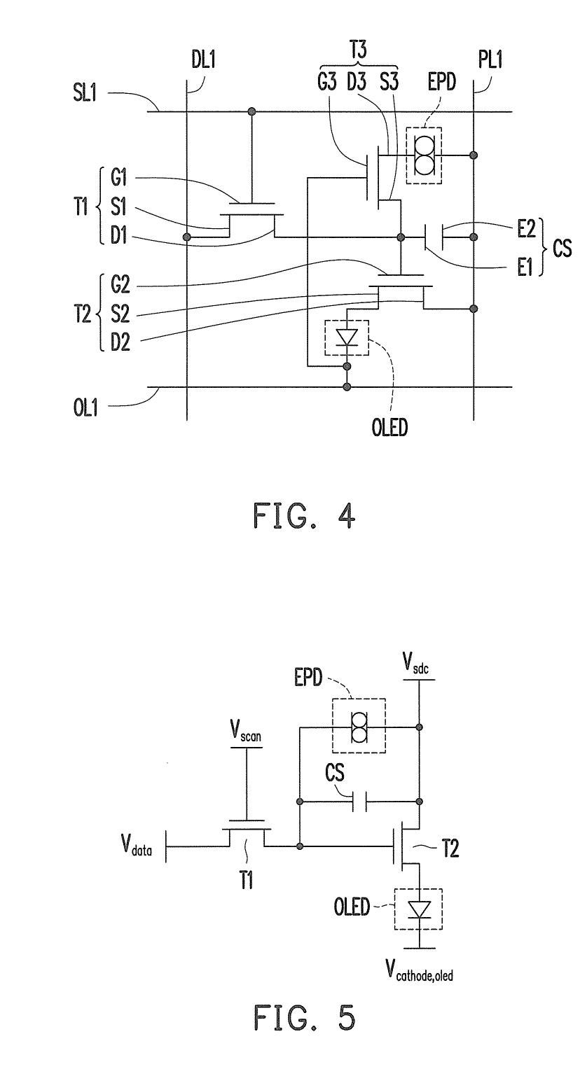

FIG. 4 is a schematic diagram illustrating a pixel structure of a hybrid display apparatus according to another exemplary embodiment. The pixel structure of FIG. 4 is similar to the pixel structure of FIG. 2, and components identical to those of FIG. 2 will be denoted with the same numerals and not repeated herein. In the exemplary embodiment of FIG. 4, the pixel structure P further comprises a third active device T3 comprising a third gate G3, a third source S3 and a third drain D3. The third active device T3 can be a top-gate thin film transistor or a bottom-gate thin film transistor. The third gate G3 of the third active device T3 is electrically connected to the second signal line OL1, the third source S3 is electrically connected to the first drain D1 of the first active device T1, and the third drain D3 is electrically connected to the electro-phoretic display device EPD (the first electrode layer 102b).

In the exemplary embodiment, the third active device T3 is further disposed between the electro-phoretic display device EPD and the storage capacitor CS. The third active device T3 may prevent the electro-phoretic display device EPD from affecting the charging ability of the storage capacitor CS. Generally speaking, since the electro-phoretic display device EPD itself has a capacitance, the capacitance the electro-phoretic display device EPD may affect the charging ability of the storage capacitor CS. Therefore, disposing the third active device T3 between the electro-phoretic display device EPD and the storage capacitor CS may prevent the electro-phoretic display device EPD from affecting the charging ability of the storage capacitor CS.

### Driving Method

Because the pixel structure P includes the electro-phoretic display device EPD and the organic light emitting diode device OLED, the hybrid display apparatus having said pixel structures P may display images with an electro-phoretic displaying mode, an organic light emitting diode displaying mode or a hybrid displaying mode.

### Electro-Phoretic Displaying Mode

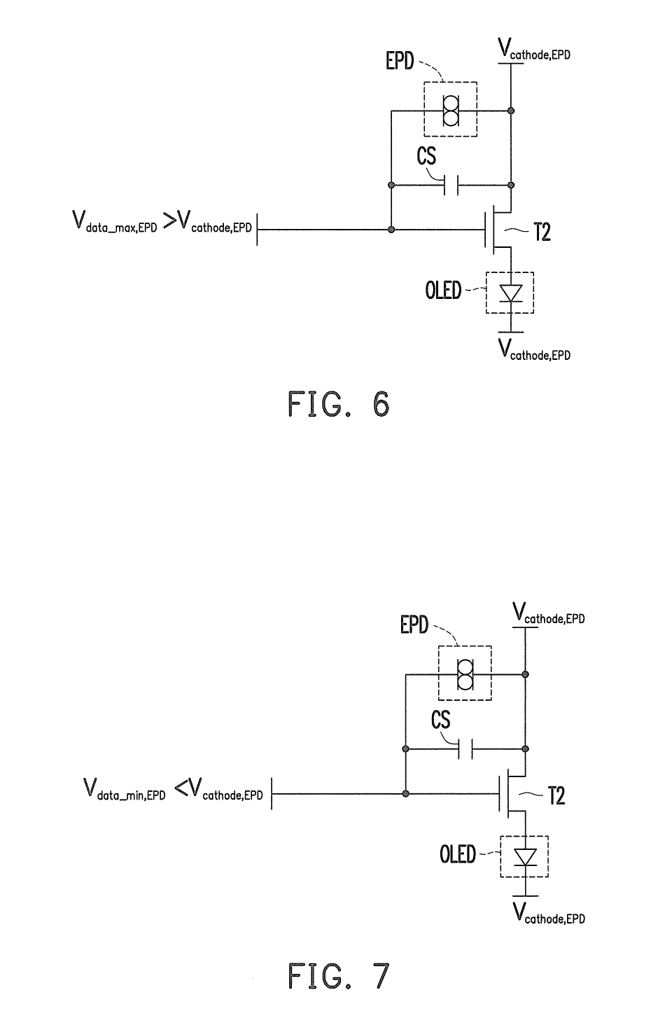

FIG. 5 is a schematic diagram illustrating a method of driving a hybrid display apparatus with an electro-phoretic displaying mode according to an exemplary embodiment. FIG. 6 and FIG. 7 are schematic equivalent circuit diagrams of the pixel structure in FIG. 5.

Referring to FIG. 1 and FIG. 5, in the exemplary embodiment, the scan lines SL1˜SLi of the pixel structures P are electrically connected to a scan voltage (V_{scan}), the data lines DL1˜DLj of the pixel structures P are electrically connected to a data voltage (V_{data}), the first signal lines PL1˜PLj of the pixel structures P are electrically connected to a driving voltage (V_{sdc}), and the second signal lines OL1˜OLi of the pixel structures P are electrically connected to a driving voltage (V_{cathode, oled}).

When the hybrid display apparatus having the pixel structures P (as shown in FIG. 1 and FIG. 2) displays an image with the electro-phoretic displaying mode, the operation voltages for each of the pixel structures P is as shown in Table 1-1.

TABLE 1-1

| Element | Operation voltage |
|---|---|
| Scan line (V_{scan}) | ≧V_{T} |
| Data line (V_{data}) | V_{data max, EPD}~V_{data min, EPD} |
| First signal line (V_{sdc}) | V_{cathode,EPD} |
| Second signal line (V_{cathode, oled}) | V_{cathode,EPD} |

In other words, when the hybrid display apparatus is displayed with the electro-phoretic displaying mode, the scan voltage (V_{scan}) for the scan lines SL˜SLi is a driving voltage (V_{T}), the data voltage (V_{data}) for the data lines DL1˜DLj is a first driving voltage (V_{data}_{_{—}}_{max, EPD}˜V_{data}_{_{—}}_{min, EPD}), the driving voltage (V_{sdc}) for the first signal lines PL1˜PLj is a second driving voltage (V_{cathode,EPD}), and the driving voltage (V_{cathode, oled}) for the second signal lines OL1˜OLi is also the second driving voltage (V_{cathode,EPD}). The first driving voltage (V_{data}_{_{—}}_{max, EPD}˜V_{data}_{_{—}}_{min, EPD}) is a data signal of the electro-phoretic display device EPD. The second driving voltage (V_{cathode,EPD}) is a cathode driving voltage of the electro-phoretic display device EPD.

When the pixel structure P is driven with the operation voltages as listed in Table 1-1, the equivalent circuit diagrams of the pixel structure P are as shown in FIG. 6 and FIG. 7. FIG. 6 is a schematic equivalent circuit diagram when the pixel structure P is driven as a white state. FIG. 7 is a schematic equivalent circuit diagram when the pixel structure P is driven as a black state.

Referring to FIG. 6, when the data voltage (V_{data}) for the data line is the first driving voltage (V_{data}_{_{—}}_{max, EPD}) which is larger than the cathode driving voltage of the electro-phoretic display device EPD (V_{cathode,EPD}), and the driving voltage (V_{sdc}) for the first signal line and the driving voltage (V_{cathode, oled}) for the second signal line are both the second driving voltage (V_{cathode,EPD}), the electro-phoretic display device EPD of the pixel structure P may be driven as a white state. In the exemplary embodiment, the second driving voltage (V_{cathode,EPD}) may be a ground voltage or zero voltage, but it does not limit herein. At this moment, because the two electrode layers of the organic light emitting diode device OLED are applied with the same voltage (V_{cathode,EPD}), the organic light emitting diode device OLED is not operated. In addition, because the two electrode layers of the electro-phoretic display device EPD are respectively applied with the first driving voltage (V_{data}_{_{—}}_{max, EPD}) and the second driving voltage (V_{cathode,EPD}), the electro-phoretic display device EPD is driven as a white state.

Referring to FIG. 7, when the data voltage (V_{data}) for the data line is the first driving voltage (V_{data}_{_{—}}_{min, EPD}) which is lower than the cathode driving voltage of the electro-phoretic display device EPD (V_{cathode,EPD}), and the driving voltage (V_{sdc}) for the first signal line and the driving voltage (V_{cathode, oled}) for the second signal line are both the second driving voltage (V_{cathode,EPD}), the electro-phoretic display device EPD of the pixel structure P is driven to a black state. Similarly, the second driving voltage (V_{cathode,EPD}) may be a ground voltage or zero voltage, but it does not limit herein. At this moment, because the two electrode layers of the organic light emitting diode device OLED are applied with the same voltage (V_{cathode,EPD}), the organic light emitting diode device OLED is not operated. In addition, because the two electrode layers of the electro-phoretic display device EPD are respectively applied with the first driving voltage (V_{data}_{_{—}}_{min, EPD}) and the second driving voltage (V_{cathode,EPD}), the electro-phoretic display device EPD is driven as a black state.

Accordingly, the hybrid display apparatus may display images with the electro-phoretic displaying mode by the foregoing driving method. In particular, the pixel structure P may be driven to present a white state or a black state according to the driving method of FIG. 6 and FIG. 7, and thus the hybrid display apparatus may display black and white images.

Moreover, if the pixel structure of the hybrid display apparatus is as shown in FIG. 4 and the hybrid display apparatus is displayed with the electro-phoretic displaying mode, the operation voltages for each of the pixel structures P is as shown in Table 1-2.

TABLE 1-2

| Element | Operation voltage |
|---|---|
| Scan line (V_{scan}) | ≧V_{T} |
| Data line (V_{data}) | V_{data max, EPD}~V_{data min, EPD} |
| First signal line (V_{sdc}) | V_{cathode,EPD} |
| Second signal line (V_{cathode, oled}) | ≧V_{T} |

In other words, because the pixel structure (as shown in FIG. 4) of the hybrid display apparatus has the third active device T3 and the third gate G3 of the third active device T3 is electrically connected to the second signal line, the second signal line is applied with a threshold voltage (V_{T}) of the third active device T3. Besides, the driving methods for the scan line, the data line and the first signal line are the same or similar to that shown in Table 1-1.

### Organic Light Emitting Diode Displaying Mode

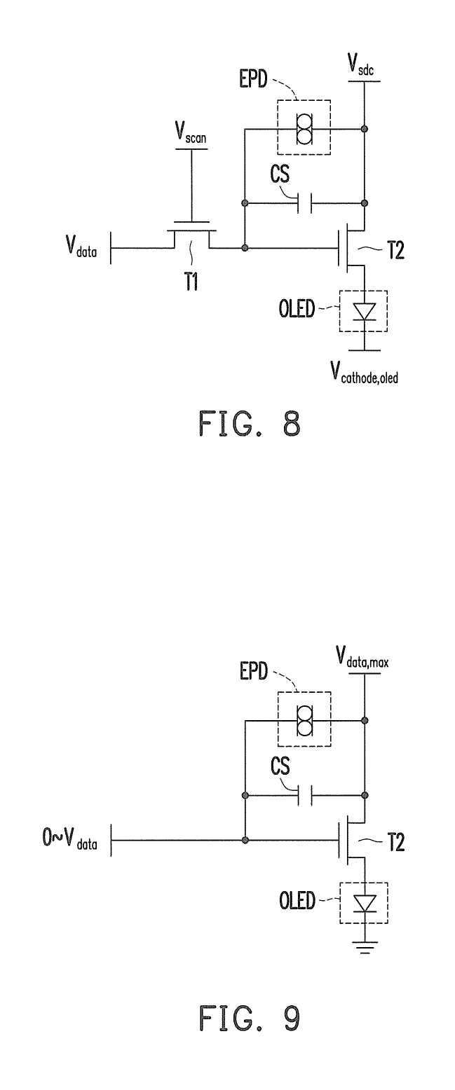

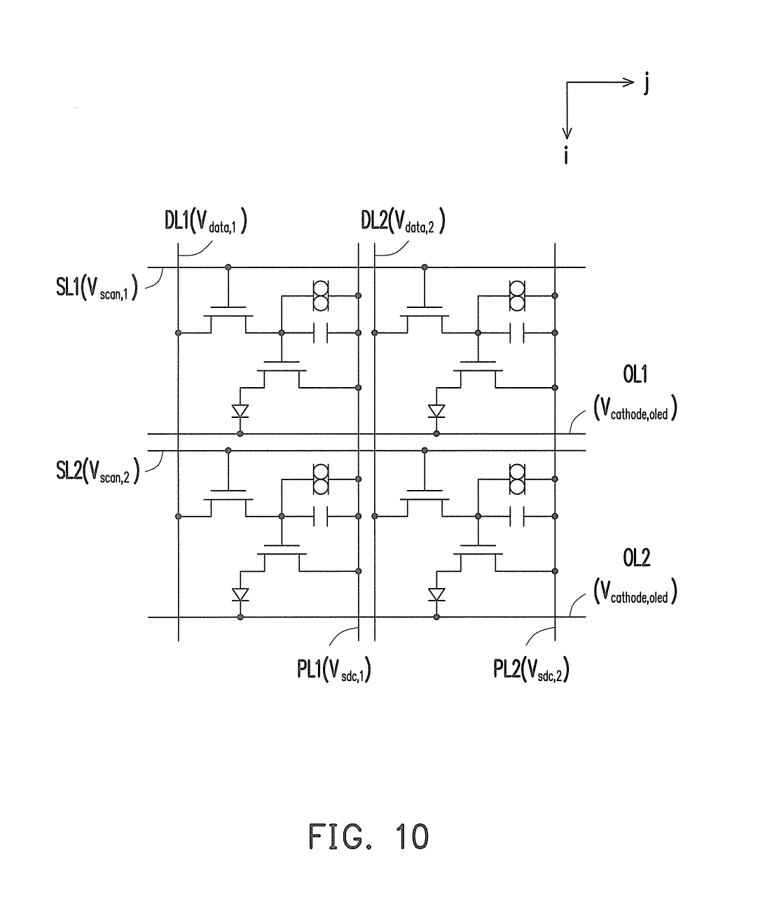

FIG. 8 is a schematic diagram illustrating a method of driving a hybrid display apparatus with an organic light emitting diode displaying mode according to an exemplary embodiment. FIG. 9 is a schematic equivalent circuit diagram of the pixel structure in FIG. 8.

Referring to FIG. 1 and FIG. 8, the scan lines SL1˜SLi of the pixel structures P are electrically connected to the scan voltage (V_{scan}), the data lines DL1˜DLj of the pixel structures P are electrically connected to the data voltage (V_{data}), the first signal lines PL1˜PLj of the pixel structures P are electrically connected to the driving voltage (V_{sdc}), and the second signal lines OL1˜OLi of the pixel structures P are electrically connected to the driving voltage (V_{cathode,oled}).

When the hybrid display apparatus having the pixel structures P displays images with an organic light emitting diode displaying mode, the operation voltages for each of the pixel structures P is as shown in Table 2-1.

TABLE 2-1

| Element | Operation voltage |
|---|---|
| Scan line (V_{scan}) | ≧V_{T} |
| Data line (V_{data}) | V_{data max, OLED}~V_{data min, OLED} |
| First signal line (V_{sdc}) | V_{data max, OLED} |
| Second signal line (V_{cathode, oled}) | ground or 0 volt |

In other words, when the hybrid display apparatus is displayed with the organic light emitting diode displaying mode, the scan voltage (V_{scan}) for the scan lines SL1˜SLi is the driving voltage (V_{T}), the data voltage (V_{data}) for the data lines DL1˜DLj is a third driving voltage (V_{data}_{_{—}}_{max, OLED}˜V_{data}_{_{—}}_{min, OLED}), the driving voltage (V_{sdc}) for the first signal lines PL1˜PLj is also the third driving voltage (V_{data}_{_{—}}_{max, OLED}), and the driving voltage (V_{cathode,oled}) for the second signal lines OL1˜OLi is a ground voltage or zero voltage. The third driving voltage (V_{data}_{_{—}}_{max, OLED}) is a driving voltage of the organic light emitting diode device OLED.

When the pixel structure P is driven with the operation voltages as listed in Table 2-1, the equivalent circuit diagram of the pixel structure P is as shown in FIG. 9. Referring to FIG. 9, when the data voltage (V_{data}) for the data line and the driving voltage (V_{sdc}) for the first signal line are both the third driving voltage (V_{data}_{_{—}}_{max, OLED}) and the driving voltage (V_{cathode, OLED}) for the second signal line is the ground voltage or zero voltage, the two electrode layers of the electro-phoretic display device EPD are applied with the same voltage (V_{data}_{_{—}}_{max, OLED}), and thereby the electro-phoretic display device EPD is not operated at this time. Moreover, the two electrode layers of the organic light emitting diode device OLED are respectively applied with the third driving voltage (V_{data}_{_{—}}_{max, OLED}) and the ground voltage (or zero voltage), and therefore the organic light emitting diode device OLED is driven to emit light at this moment.

Accordingly, the hybrid display apparatus may display images with the organic light emitting diode displaying mode by the foregoing driving method. In particular, the pixel structure P may emit color light according to the driving method of FIG. 8, and thus the hybrid display apparatus may display color images.

Moreover, if the pixel structure of the hybrid display apparatus is as shown in FIG. 4 and the hybrid display apparatus is displayed with the organic light emitting diode displaying mode, the operation voltages for each of the pixel structures P is as shown in Table 2-2.

TABLE 2-2

| Element | Operation voltage |
|---|---|
| Scan line (V_{scan}) | ≧V_{T} |
| Data line (V_{data}) | V_{data max, OLED}~V_{data min, OLED} |
| First signal line (V_{sdc}) | V_{data max, OLED} |
| Second signal line (V_{cathode, oled}) | ground or 0 volt |

In other words, even though the pixel structure (as shown in FIG. 4) of the hybrid display apparatus has the third active device T3 and the third gate G3 of the third active device T3 is electrically connected to the second signal line, the organic light emitting diode device OLED does not have relations with the third active device T3. Therefore, the driving methods for the scan line, the data line, the first signal line and the second signal line are the same or similar to that shown in Table 2-1.

### Hybrid Displaying Mode

FIG. 10 is a schematic diagram illustrating a method of driving a pixel array of a hybrid display apparatus with a hybrid displaying mode according to an exemplary embodiment.

Referring to FIG. 1 and FIG. 10, the scan lines SL1˜SLi of the pixel structures P are respectively electrically connected to a scan voltage (V_{scan, 1}˜V_{scan, i}), the data lines DL1˜DLj of the pixel structures P are respectively electrically connected to a data voltage (V_{data, 1}˜V_{data, j}), the first signal lines PL1˜PLj of the pixel structures P are respectively electrically connected to a driving voltage (V_{side, 1}˜V_{sdc, j}), and the second signal lines OL1˜OLi of the pixel structures P are electrically connected to a driving voltage (V_{cathode, oled}). In the exemplary embodiment, the driving voltage (V_{cathode, oled}) for the second signal lines OL1˜OLi is a ground voltage or zero voltage.

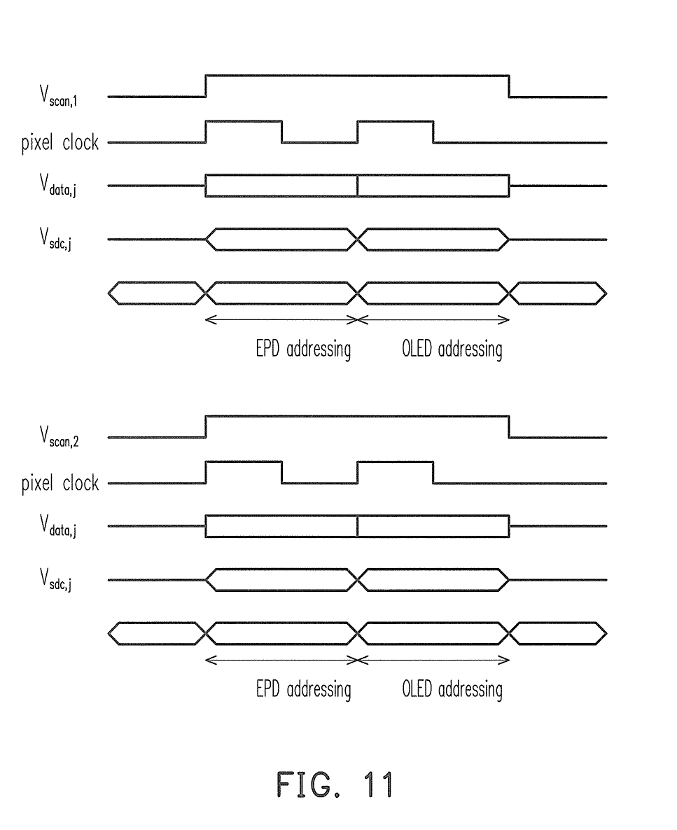

When the hybrid display apparatus having the pixel structures P displays images with a hybrid displaying mode, the operation voltages for the pixel structures P are as shown in FIG. 11. In other word, when the hybrid display apparatus is displayed with the hybrid displaying mode, the scan lines SL1˜SLi are respectively applied with the scan voltage (V_{scan, 1}˜V_{scan, i}) in accordance with a driving time sequence (pixel clock); the data lines DL1˜DLj are respectively applied with a fourth data voltage (V_{data, 1}˜V_{data, j}) in accordance with the driving time sequence (pixel clock); a portion of the first signal lines PL1˜PLj are respectively applied with a fifth voltage (V_{cathode, EPD}) in accordance with the driving time sequence (pixel clock); and another portion of the first signal lines PL1˜PLj are respectively applied with a sixth voltage (V_{data}_{_{—}}_{max, OLED}) in accordance with the driving time sequence (pixel clock). The fourth data voltage (V_{data, 1}˜V_{data, j}) is a data signal of the hybrid displaying mode, the fifth voltage (V_{cathode, EPD}) is a cathode driving voltage of the electro-phoretic display device EPD, and the sixth voltage (V_{data}_{_{—}}_{max, OLED}) is a driving voltage of the organic light emitting diode device OLED.

In the exemplary embodiment, the cathode driving voltage (V_{cathode, EPD}) of the electro-phoretic display device EPD and the driving voltage (V_{data}_{_{—}}_{max, OLED}) of the organic light emitting diode device OLED are switched through switching the driving voltage (V_{sdc}) of first signal lines PL1˜PLj, such that the pixel structures P can be respectively controlled to be displayed with the organic light emitting diode displaying mode or the electro-phoretic displaying mode. Therefore, the hybrid display apparatus having said pixel structures may display an image simultaneously with the organic light emitting diode displaying mode and the electro-phoretic displaying mode.

### Driving System

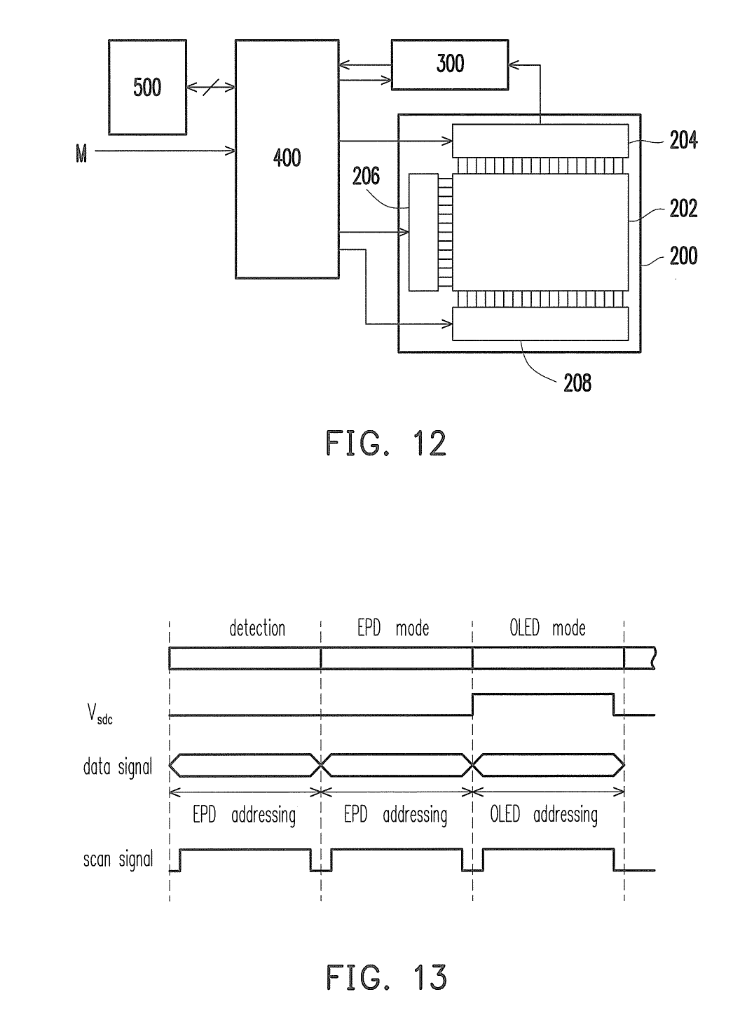

FIG. 12 is a schematic diagram illustrating a driving system of a hybrid display apparatus according to an exemplary embodiment. Referring to FIG. 12, the driving system comprises a hybrid display apparatus 200, a detection unit 300 and a control unit 400.

The hybrid display apparatus 200 includes a pixel array 202 as shown in FIG. 1, and each of the pixel structures of the pixel array 202 can be the pixel structure as shown in FIG. 2, FIG. 3A and FIG. 3B or the pixel structure as shown in FIG. 4. In addition, the hybrid display apparatus 200 further comprises a data driving device 204, a scan driving device 206 and a signal line control unit 208. The data lines (such as the data line DL1˜DLj as shown in FIG. 1) of the pixel array 202 are electrically connected to the data driving device 204, the scan lines (such as the scan line SL1˜SLj as shown in FIG. 1) of the pixel array 202 are electrically connected to the scan driving device 206, and the first signal lines (such as the scan line PL1˜SPLj as shown in FIG. 1) of the pixel array 202 are electrically connected to the signal line control unit 208.

The detection unit 300 is electrically connected to the hybrid display apparatus 200. The control unit 400 is electrically connected to the hybrid display apparatus 200 and the detection unit 300. In the exemplary embodiment, the driving system may further comprise a memory unit 500, but it is not limited in the embodiment. The operation method of the driving system is as shown in FIG. 13.

Referring to FIG. 12 and FIG. 13, when the hybrid display apparatus 200 is powered-on, the detection unit 300 performs a detecting step, such that the electro-phoretic display devices EPD of the pixel array 202 are performed with a resetting process. Herein, the resetting process means that all of the electro-phoretic display devices EPD of the pixel array 202 are driven to present a white state or a black state. At this time period, the data voltage (V_{data}) transmitted from the data driving device 204 to the data lines is V_{data}_{_{—}}_{max, EPD} or V_{data}_{_{—}}_{min, EPD}, and the driving voltage transmitted from the signal line control unit 208 to the first signal lines is V_{cathode, EPD}.

Generally, the response rate of the electro-phoretic display devices EPD is lower than the response rate of the organic light emitting diode OLED. The resetting process performed after the hybrid display apparatus 200 is powered-on may firstly drive the electro-phoretic display devices EPD of the pixel array 202, such that the hybrid display apparatus 200 may have better displaying quality when the user uses the hybrid display apparatus 200. In addition, if the electro-phoretic display devices EPD of the pixel array 202 are driven to present a black state during the resetting process, displaying contrast of the hybrid display apparatus 200 may also be enhanced when the hybrid display apparatus 200 displays images with the organic light emitting diode displaying mode.

After the hybrid display apparatus 200 is powered-on, when an image signal M is transmitted to the control unit 400, the detection unit 300 detects the image signal M, and then the detection unit 300 transmits a detecting signal to the control unit 400. Thereafter, the control unit 400 drives the hybrid display apparatus 200 to display an image in accordance with the detecting signal. If the image signal M detected by the detection unit 300 is suitably displayed with the electro-phoretic displaying mode, the control unit 400 drives the hybrid display apparatus 200 to display the image with the electro-phoretic displaying mode according to the detecting signal. If the image signal M detected by the detection unit 300 is suitably displayed with the organic light emitting diode displaying mode, the control unit 400 drives the hybrid display apparatus 200 to display the image with the organic light emitting diode displaying mode according to the detecting signal. If the image signal M detected by the detection unit 300 is suitably displayed with the hybrid displaying mode, the control unit 400 drives the hybrid display apparatus 200 to display the image with the hybrid displaying mode according to the detecting signal. In an embodiment, if the image signal M is a black and white image (such as an image with black words), it is preferable to display the image signal M with the electro-phoretic displaying mode. If the image signal M is a color image (such as color picture or color dynamic image), it is preferable to display the image signal M with the organic light emitting diode displaying mode. If the image signal M simultaneously has a black and white image (such as an image with black words) and a color image (such as color picture or color dynamic image), it is preferable to display the image signal M with the hybrid displaying mode. However, it is not limited to the embodiment.

Furthermore, the user may also adjust or set the displaying mode of the hybrid display apparatus 200. If the detection unit 300 detects the hybrid display apparatus 200 has been adjusted or set as the electro-phoretic displaying mode, the organic light emitting diode displaying mode or the hybrid displaying mode, the control unit 400 drives the hybrid display apparatus 200 to display images with the electro-phoretic displaying mode, the organic light emitting diode displaying mode or the hybrid displaying mode according to the detecting signal.

For details, if the control unit 400 drives the hybrid display apparatus 200 to display images with the electro-phoretic displaying mode according to the detecting signal of the detection unit 300, the scan driving device 206 transmits the driving voltage (V_{T}) to the scan lines; the data driving device 204 transmits the first driving voltage (V_{data}_{_{—}}_{max, EPD}˜V_{data}_{_{—}}_{min, EPD}) to the data lines, the signal line control unit 208 transmits the second driving voltage (V_{cathode, EPD}) to the first signal lines, and the second signal lines are electrically connected to a ground voltage or zero voltage. The driving method is as listed in Table 1-1 and Table 1-2, and the equivalent circuit diagrams of the pixel structure are as shown in FIG. 6 and FIG. 7.

If the control unit 400 drives the hybrid display apparatus 200 to display images with the organic light emitting diode displaying mode according to the detecting signal of the detection unit 300, the scan driving device 206 transmits the driving voltage (V_{T}) to the scan lines; the data driving device 204 transmits the third driving voltage (V_{data}_{_{—}}_{max, OLED}) to the data lines, the signal line control unit 208 also transmits the third driving voltage (V_{data}_{_{—}}_{max, OLED}) to the first signal lines, and the second signal lines are electrically connected to a ground voltage or zero voltage. The driving method is as listed in Table 2-1 and Table 2-2, and the equivalent circuit diagram of the pixel structure are as shown in FIG. 9.

If the control unit 400 drives the hybrid display apparatus 200 to display images with the hybrid displaying mode according to the detecting signal of the detection unit 300, the scan driving device 206 transmits the driving voltage (V_{T}) to the scan lines; the data driving device 204 transmits the fourth driving voltage (V_{data, 1}˜V_{data, j}) to the data lines, the signal line control unit 208 transmits the fifth driving voltage (V_{cathode, EPD}) to the first signal lines of a portion of the pixel structures, and the signal line control unit 208 transmits the sixth driving voltage (V_{data}_{_{—}}_{max, OLED}) to the lines of another portion of the pixel structures. The driving method is as shown in FIG. 10 and FIG. 11.

The detection unit 300 may also detect other conditions in addition to the image signal M.

According to an exemplary embodiment, the detection unit 300 further detects an environmental condition, and the control unit 400 drives the hybrid display apparatus 200 to display the image in accordance with the environmental condition. The environmental condition comprises an environmental temperature, for example. Because the driving voltage of the electro-phoretic display devices slightly related to the environmental temperature, the control unit 400 may adjust the driving voltage of the electro-phoretic display devices of the pixel structures in accordance with the environmental temperature. Said driving voltage of the electro-phoretic display devices includes the data voltage (V_{data}_{_{—}}_{max, EPD}˜V_{data}_{_{—}}_{min, EPD}) of the data lines and driving voltages (V_{cathode, EPD}) of the first signal lines.

According to another exemplary embodiment, the detection unit 300 further detects light emitting intensity of the organic light emitting diode devices of the pixel array 202 of the hybrid display apparatus 200, and the control unit 400 adjusts a driving voltage of the organic light emitting diode devices of pixel array 202 of the hybrid display apparatus 200 in accordance with the light emitting intensity. Because the light emitting intensity of the organic light emitting diode devices may decay upon their lift-time, the control unit 400 may adjust the driving voltage of the organic light emitting diode devices of pixel array 202 of the hybrid display apparatus 200 in accordance with the detected light emitting intensity. The driving voltage of the organic light emitting diode devices includes the data voltage of the data lines and the driving voltages (V_{data}_{_{—}}_{max, OLED}) of the first signal lines.

In light of the foregoing, the electro-phoretic display devices and the organic light emitting diode devices are integrated to a display apparatus to form the hybrid display apparatus, and the electro-phoretic display device and the organic light emitting diode device in one pixel structure are driven with the same driving device. The hybrid display apparatus can be displayed with a suitable displaying mode in accordance with demands. In particular, if the hybrid display apparatus is displayed with a hybrid displaying mode, reading convenience can be enhanced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A pixel structure of a hybrid display apparatus, comprising:
a scan line and a data line;
a first active device, electrically connected to the scan line and the data line;
a first signal line and a second signal line;
an electro-phoretic display device, electrically connected to the first active device and the first signal line;
a second active device, electrically connected to the first active device and the first signal line; and
an organic light emitting diode device, electrically connected to the second active device and the second signal line.

2. The pixel structure as claimed in claim 1, wherein the first active device comprises a first gate, a first source and a first drain, the second active device comprises a second gate, a second source and a second drain, and the first drain is electrically connected to the second gate.

3. The pixel structure as claimed in claim 2, wherein the second source is electrically connected to the first signal line, and the second drain is electrically connected to the organic light emitting diode device.

4. The pixel structure as claimed in claim 2, further comprising a storage capacitor having a first capacitor electrode and a second capacitor electrode, wherein the first capacitor electrode is electrically connected to the first drain, and the second capacitor electrode is electrically connected to the second source and the first signal line.

5. The pixel structure as claimed in claim 2, wherein the electro-phoretic display device comprises:
a first electrode layer, electrically connected to the first drain;
a second electrode layer, electrically connected to the first signal line; and
an electro-phoretic display medium, disposed between the first electrode layer and the second electrode layer.

6. The pixel structure as claimed in claim 5, wherein the electro-phoretic display medium and the second electrode layer of the electro-phoretic display device cover the organic light emitting diode device.

7. The pixel structure as claimed in claim 2, wherein the organic light emitting diode device comprises:
a first electrode layer, electrically connected to the second drain;
an organic light emitting layer, disposed on the first electrode layer; and
a second electrode layer, disposed on the organic light emitting layer and electrically connected to the second signal line.

8. The pixel structure as claimed in claim 2, further comprising a third active device having a third gate, a third source and a third drain, wherein the third gate is electrically connected to the second signal line, the third source is electrically connected to the first drain, and the third drain is electrically connected to the electro-phoretic display device.

9. A method of driving a hybrid display apparatus, comprising:
providing a hybrid display apparatus comprising a plurality of pixel structures, wherein each of the pixel structures is as claimed in claim 1;
when the hybrid display apparatus is displayed with an electro-phoretic displaying mode, a driving voltage is applied to the scan lines of the pixel structures, a first driving voltage is applied to the data lines of the pixel structures, and a second driving voltage is applied to the first signal lines and the second signal lines of the pixel structures;
when the hybrid display apparatus is displayed with an organic light emitting diode displaying mode, the driving voltage is applied to the scan lines of the pixel structures, a third driving voltage is applied to the data lines and the first signal lines of the pixel structures, and a ground voltage or zero voltage is applied to the second signal lines of the pixel structures; and
when the hybrid display apparatus is displayed with a hybrid displaying mode, the driving voltage is applied to the scan lines of the pixel structures, a fourth driving voltage is applied to the data lines of the pixel structures, a fifth driving voltage is applied to the first signal lines of a portion of the pixel structures, and a sixth driving voltage is applied to the first signal lines of another portion of the pixel structures.

10. The method as claimed in claim 9, wherein the first driving voltage is a data signal of the electro-phoretic display device, and the second driving voltage is a cathode driving voltage of the electro-phoretic display device.

11. The method as claimed in claim 9, wherein the third driving voltage is a driving voltage of the organic light emitting diode device.

12. The method as claimed in claim 9, wherein the fourth driving voltage is a data signal of the hybrid displaying mode, the fifth driving voltage is a cathode driving voltage of the electro-phoretic display device, and the sixth driving voltage is a driving voltage of the organic light emitting diode device.

13. A driving system of a hybrid display apparatus, comprising:
a hybrid display apparatus comprising a plurality of pixel structures, wherein each of the pixel structures is as claimed in claim 1;
a detection unit, electrically connected to the hybrid display apparatus;
a control unit, electrically connected to the hybrid display apparatus and the detection unit, wherein
when the hybrid display apparatus is powered-on, the detection unit performs a detecting step, such that the electro-phoretic display devices of the pixel structures are performed with a resetting process; and
when an image signal is transmitted to the control unit, the detection unit detects the image signal and transmits a detecting signal to the control unit, and the control unit drives the hybrid display apparatus to display an image in accordance with the detecting signal.

14. The system as claimed in claim 13, wherein when the control unit drives the hybrid display apparatus to display the image with an electro-phoretic displaying mode, a driving voltage is applied to the scan lines of the pixel structures of the hybrid display apparatus, a first driving voltage is applied to the data lines of the pixel structures, and a second driving voltage is applied to the first signal lines and the second signal lines of the pixel structures.

15. The system as claimed in claim 13, wherein when the control unit drives the hybrid display apparatus to display the image with an organic light emitting diode displaying mode, a driving voltage is applied to the scan lines of the pixel structures of the hybrid display apparatus, a third driving voltage is applied to the data lines and the first signal lines of the pixel structures, and a ground voltage or zero voltage is applied to the second signal lines of the pixel structures.

16. The system as claimed in claim 13, wherein when the control unit drives the hybrid display apparatus to display the image with a hybrid displaying mode, a driving voltage is applied to the scan lines of the pixel structures of the hybrid display apparatus, a fourth driving voltage is applied to the data lines of the pixel structures, a fifth driving voltage is applied to the first signal lines of a portion of the pixel structures, and a sixth driving voltage is applied to the first signal lines of another portion of the pixel structures.

17. The system as claimed in claim 13, wherein the detection unit further detects an environmental condition, and the control unit drives the hybrid display apparatus to display the image in accordance with the environmental condition.

18. The system as claimed in claim 17, wherein the environmental condition comprises an environmental temperature, and the control unit adjusts a driving voltage of the electro-phoretic display devices of the pixel structures of the hybrid display apparatus in accordance with the environmental temperature.

19. The system as claimed in claim 13, wherein the detection unit further detects light emitting intensity of the organic light emitting diode devices of the pixel structures of the hybrid display apparatus, and the control unit adjusts a driving voltage of the organic light emitting diode devices of the pixel structures of the hybrid display apparatus in accordance with the light emitting intensity.
